(19) United States
(12) Patent Application Publication
(10) Pub. No.: US 2006/0234412 A1
(43) Pub. Date: Oct. 19, 2006

(54) MEMS release methods

(75) Inventor: Dennis M. Lazaroff, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: Hewlett-Packard Development Company, L.P. Intellectual Property Administration, Fort Collins, CO (US)

(21) Appl. No.: 11/110,132

(22) Filed: Apr. 19, 2005

(51) Int. Cl. H01L 21/00

(52) U.S. Cl. 438/48

(57) ABSTRACT

A packaged MEMS device is fabricated by providing a first substrate, forming the MEMS device on the first substrate (the MEMS device including at least one element initially held immobile by a sacrificial material), optionally removing a portion of the sacrificial material without releasing the element, providing a second substrate, forming at least one release port, bonding the second substrate to the first substrate, and removing the sacrificial material through the release port to release the element.

### CROSS-REFERENCE TO RELATED APPLICATION

This application is related to co-pending and commonly assigned application Ser. No. ______, filed on Apr. 11, 2005 (attorney docket no. 200501403-1).

### TECHNICAL FIELD

This invention relates generally to microfabrication methods and, more particularly, to methods for making micro-electro-mechanical (MEMS) devices and to the MEMS devices made.

### BACKGROUND

In fabrication of microelectromechanical system (MEMS), deflectable or movable structures are typically produced by etching features into a device layer, using silicon processing techniques common to the semiconductor industry to form the structure's form. The deflectable structures are often held immobile initially by a layer of sacrificial material. Typically, the layer of sacrificial material underlies the deflectable or movable structure. The underlying sacrificial layer is subsequently removed (e.g., by preferential etching) in a release process to produce a suspended deflectable structure or, in some cases, a free element. Often the structural device layer is silicon, silicon compound, a metal, or an alloy. Various sacrificial materials, such as silicon dioxide, photoresist, polyimide, epoxy, wax, polysilicon, and amorphous silicon, have been used for the sacrificial layer. Some MEMS devices are made by using two or more sacrificial materials for support, immobilization, and/or release of different structures of the MEMS device, which may have more than one structural device layer. The various sacrificial materials may be removed by the same etch process or by different selective etch processes. For example, a first sacrificial material or a portion of it may be removed by a wet etch and a second sacrificial material and/or a remaining portion of the first sacrificial material may be removed by a plasma etch.

Some specific sacrificial materials and etchants that have been used with the sacrificial materials include silicon oxide, removed, e.g., by hydrofluoric acid (HF) or buffered HF etching; amorphous silicon, removed, e.g., by xenon difluoride (XeF₂) etching; and organic materials such as photoresist removed by oxygen plasma ashing.

After release by removal of the sacrificial material(s), the MEMS structures may be subject to ambient conditions which can lead to particulate and chemical contamination while the MEMS wafer is being stored, being inspected, or being prepared for packaging. Standard practice in MEMS fabrication often includes enclosing the MEMS devices within a package that protects the MEMS devices from environmental effects after MEMS release. The package may be hermetic, and the MEMS fabrication process may include bonding.

It has been reported that the greatest single cause of yield problems in fabrication of MEMS structures is “stiction,” unwanted adhesion of a MEMS structural element to another surface. Various coating materials have been employed to help prevent stiction. Such anti-stiction coatings are commonly applied after release of the MEMS device structures. Some anti-stiction coatings that have been used include amorphous hydrogenated carbon, perfluoropolyethers, perfluorodecanoic acid, polytetrafluoroethylene (PTFE), diamond-like carbon, and an alkyltrichlorosilane monolayer lubricant. Dessicants are also sometimes used in MEMS packages to help keep moisture away from device structures.

When bonding of a package seal occurs after MEMS release, packaging processes, including desiccant introduction or anti-stiction coating, can lead to particulate generation and chemical contaminants on the MEMS devices.

Other steps of many packaging procedures may require processes that can also adversely affect the MEMS structures if they are in a fully released state. For example, soldering or anodic bonding can lead to thermally or electrically induced strain and/or bending in the MEMS structures. Radiation, e.g., ultraviolet (UV) radiation used for curing epoxies, has the potential to damage fragile circuits through solid-state interactions with high-energy photons and can indirectly lead to heating, causing problems as described with reference to soldering or anodic bonding. High electric fields, such as the fields that may occur in anodic bonding, can damage MEMS by causing “snap-down,” charge-trapping, and other unwanted electrical phenomena. Outgassing of organic materials, e.g., in adhesive curing, can lead to surface adsorbed contamination of sensitive MEMS areas causing corrosion, stiction, charge-trapping, or other dielectric-related phenomena. Deposition of an anti-stiction coating after MEMS release, but before plasma-assisted bonding, may lead to fouling of the bonding surfaces. Conversely, high-temperature bonding processes may adversely affect the anti-stiction coating. Thus, if the anti-stiction coating is placed in or on the MEMS device after release, but before package seal bonding, process integration problems may arise, such as surfaces that will no longer bond, or, an anti-stiction coating that loses functionality for the MEMS due to thermally induced chemical changes.

Thus, an improved MEMS fabrication method is needed to minimize or avoid these shortcomings of the prior art.

### BRIEF DESCRIPTION OF THE DRAWINGS

The features and advantages of the disclosure will readily be appreciated by persons skilled in the art from the following detailed description when read in conjunction with the drawings, wherein:

FIG. 1 is a flowchart illustrating an embodiment of a method for fabricating MEMS devices.

FIGS. 2A, 3A, 4A, 5A, and 6A are top plan views of an embodiment of a MEMS device at various stages of its fabrication.

FIGS. 2B, 3B, 4B, 5B, and 6B are side elevation cross-sectional views of an embodiment of a MEMS device at various stages of its fabrication.

### DETAILED DESCRIPTION OF EMBODIMENTS

For clarity of the description, the drawings are not drawn to a uniform scale. In particular, vertical and horizontal scales may differ from each other and may vary from one drawing to another. In this regard, directional terminology, such as “top,” “bottom,” “front,” “back,” “leading,” “trailing,” etc., is used with reference to the orientation of the drawing figure(s) being described. Because components of the invention can be positioned in a number of different orientations, the directional terminology is used for purposes of illustration and is in no way limiting.

The terms “microfabrication” and “MEMS” as used herein are not meant to exclude structures characterized by nanoscale dimensions, i.e., a scale corresponding generally to the scale in the definition of U.S. Patent Class 977, generally less than about 100 nanometers (nm). Nor are these terms meant to exclude methods for making such nanoscale structures.

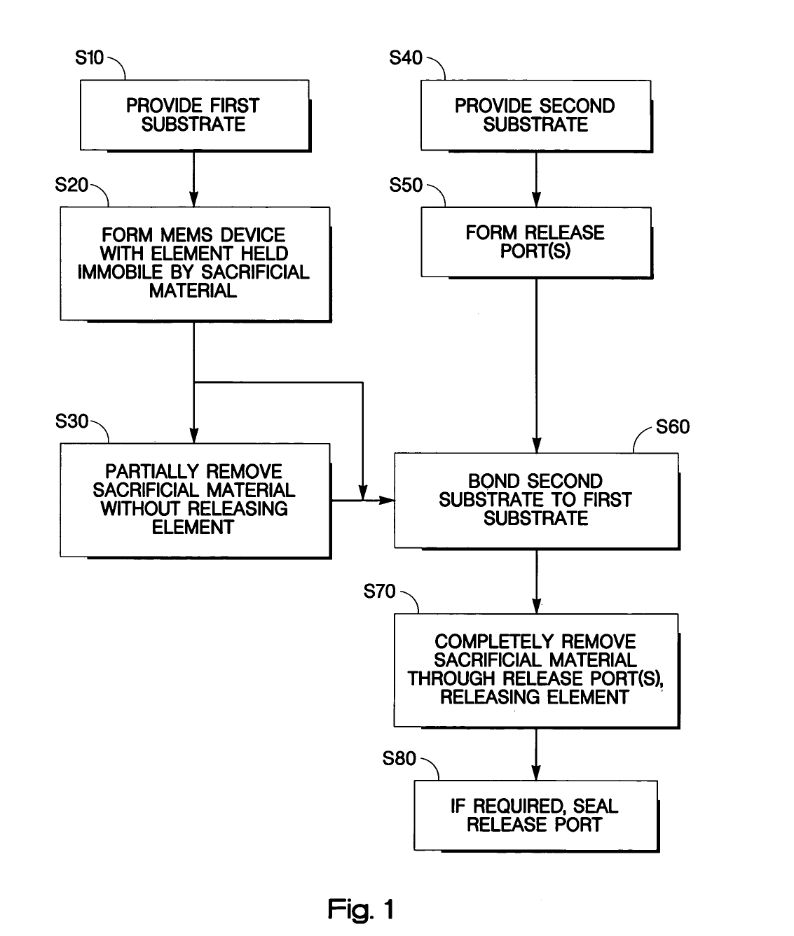

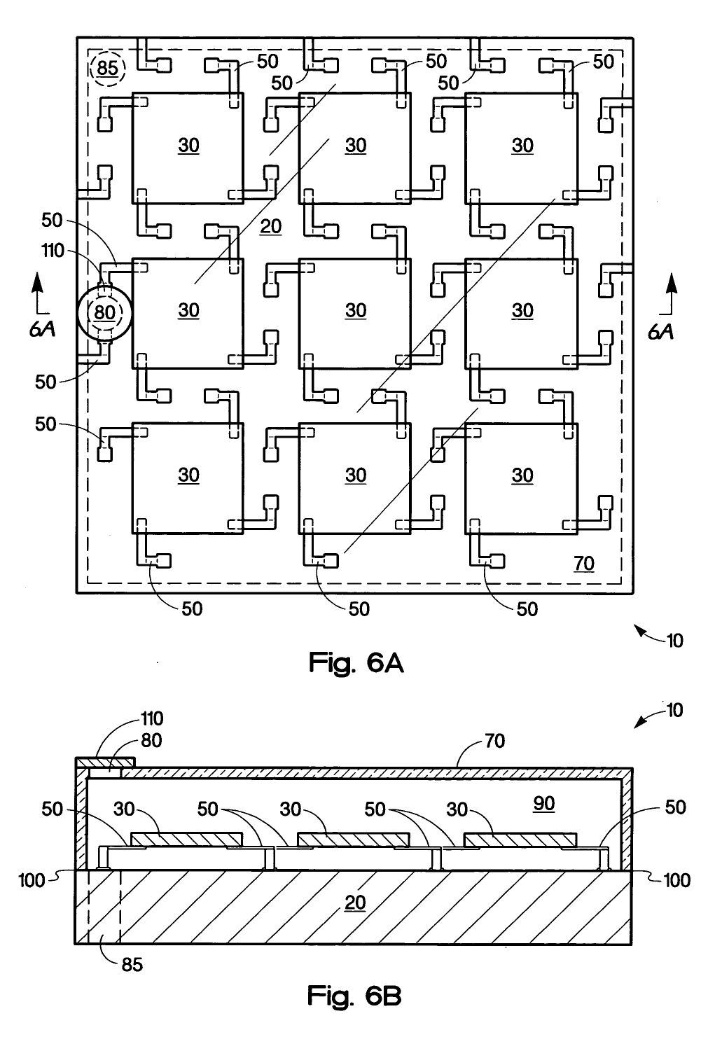

As illustrated by FIG. 1, one aspect of the invention provides embodiments of a method of fabricating a packaged MEMS device 10 (FIGS. 6A and 6B) by providing a first substrate, forming the MEMS device on the first substrate (the MEMS device including at least one element initially held immobile by a sacrificial material), optionally removing a portion of the sacrificial material without releasing the element, providing a second substrate, forming at least one release port, bonding the second substrate to the first substrate, and removing the sacrificial material completely through the release port to release the element.

If a sealed environment is required for the MEMS device, the release port or ports may be sealed.

Thus, specific embodiments of such methods include removing a first portion of the sacrificial material before performing the step of bonding the second substrate to the first substrate, while leaving a second portion of the sacrificial material to be removed through the release port. Thus, a portion of the sacrificial material may be removed (e.g., by partial etching, which may be a wet etch) without releasing the immobilized element(s), leaving an amount of sacrificial material sufficient to hold the element(s) immobile until they are released later (after bonding the substrates) as described above.

Both the first and second substrates may be planar or have substantially planar portions where the two substrates are bonded. The first substrate may comprise a material such as silicon, an oxide of silicon, an oxynitride of silicon, a nitride of silicon, a metal, an oxide of a metal, an oxynitride of a metal, a nitride of a metal, or combinations of these materials, for example. The second substrate may comprise a material such as glass, quartz, alumina, silicon, an oxide of silicon, an oxynitride of silicon, a nitride of silicon, a metal, an oxide of a metal, an oxynitride of a metal, a nitride of a metal, or combinations of these materials, for example.

The release port or ports may extend through either (or both) of the first or second substrates, or may be disposed in the bond formed between the substrates. Where the MEMS device might be damaged due to proximity of a release port, the release port(s) may be disposed to avoid alignment with the MEMS device(s). Thus, an axis of the release port may be disposed to be laterally spaced apart from the MEMS device.

In a particular embodiment of a method for fabricating a packaged MEMS device, the steps may include providing a first substrate; forming the MEMS device on the first substrate, the MEMS device including at least one element initially held immobile by a sacrificial material; removing a first portion of the sacrificial material without releasing the element initially held immobile, while leaving a second portion of the sacrificial material to be removed later; providing a second substrate; forming at least one release port; bonding the second substrate to the first substrate; and completely removing the second portion of the sacrificial material through the release port to release the element that was initially held immobile. In this embodiment, again, if a sealed environment is required for the MEMS device, the release port or ports may be sealed.

Such embodiments of methods are illustrated in FIG. 1, which shows a flowchart, with steps identified by reference numerals S10, S20, . . . , S80. In step S10, a first substrate is provided, and a MEMS device is formed (step S20), with an element initially held immobile by a sacrificial material. Those skilled in the art will recognize that a number of MEMS devices may be formed simultaneously, and the MEMS devices may also be arranged in an array, e.g. on a planar silicon wafer. Various sacrificial materials have been used, such as silicon dioxide, polyimide, epoxy, wax, polysilicon, and amorphous silicon. One of these materials or another sacrificial material may be chosen, depending on the MEMS device and/or the requirements of a particular application.

In step S30, the sacrificial material may be partially removed without releasing the element that was initially held immobile (by removing only a portion of the sacrificial material while leaving a second portion of the sacrificial material to be removed later). This partial removal of sacrificial material may be performed by a suitable wet etch, for example, timed to leave a portion of sacrificial material in place. Those skilled in the art will recognize that the etchant should be chosen which is suitable to selectively etch the sacrificial material used, with an etch-rate ratio or ratios suitable to avoid affecting functionality of the MEMS device.

In step S40, a second substrate is provided. The second substrate may provide a protective cover to cover the MEMS device. For example, the second substrate may be a glass substrate if a transparent cover is required, such as for optical applications of the MEMS device. A planar second substrate may have one or more seal rings formed on it for bonding to the first substrate. In step S50, one or more release ports are formed.

In step S60, the two substrates are bonded together. For example, the cover and the silicon wafer may be plasma treated and bonded to form an oxide-to-oxide bond. Many other methods for bonding two substrates together, such as anodic bonding and adhesive bonding, are known in the art. Unlike the standard MEMS processing which includes release etching before bonding, the MEMS structures of the present invention are not exposed to ambient conditions which can lead to particulate and chemical contamination before they are packaged. The present packaging process can reduce and possibly eliminate particulate exposure on the MEMS devices. Thermal excursions of the bonding process cannot greatly strain the MEMS devices because they are still held immobile by sacrificial material such as amorphous silicon. Ultraviolet (UV) adhesives can be utilized for non-hermetic packaging, if desired, since the MEMS are protected by the encapsulating sacrificial material from outgassing or UV radiation. Anodic bonding can be utilized, if desired, since the MEMS devices are held firmly in place and cannot “snap-down” from electrostatic forces. Anti-stiction coating can be applied at an appropriate time through the release ports if desired, e.g. by a chemical vapor deposition (CVD) process.

In step S70, the sacrificial material is completely removed through the release port(s), releasing the element or elements that were initially held immobile by the sacrificial material. For example, if amorphous silicon is used as the sacrificial material, the whole assembly may be placed in an etching chamber (an XeF₂ etcher, for example). The etchant attacks sacrificial material, and etching proceeds until all the required sacrificial material is etched from the MEMS array, i.e., until the MEMS structures are released.

In step S80, the release port may be sealed (if required) after releasing the immobilized element(s). A number of such lateral release ports may be used for each MEMS device.

An array of MEMS devices may be fabricated on a single substrate such as a silicon wafer, each MEMS device having one or more lateral release ports. The methods disclosed herein may be practiced at a wafer level of processing, i.e., before dicing or singulation of the wafer.

Another aspect of the invention provides embodiments of a packaged MEMS device 10 comprising a first substrate carrying the MEMS device, the MEMS device including at least one element initially held immobile by a sacrificial material, a second substrate having at least one release port for removing the sacrificial material, and a bond joining the second substrate to the first substrate. Some embodiments of the packaged MEMS device may further comprise a seal for closing the release port(s) after removing the sacrificial material to release the element initially held immobile.

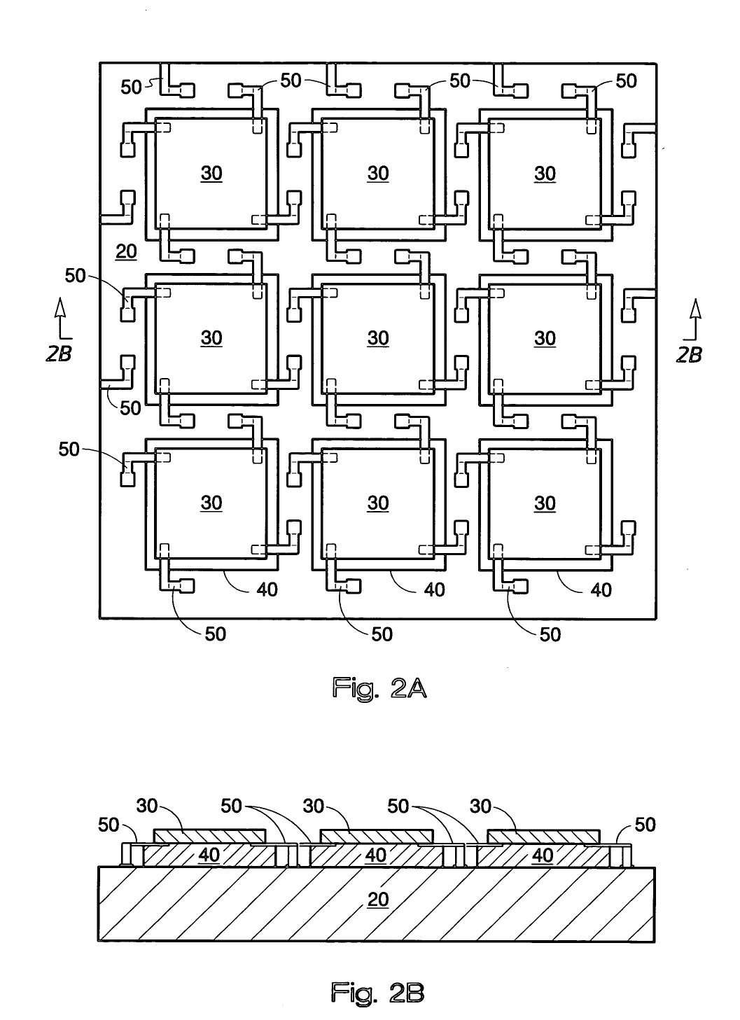

FIGS. 2A, 3A, 4A, 5A, and 6A are top plan views, and FIGS. 2B, 3B, 4B, 5B, and 6B are side elevation cross-sectional views of an embodiment of such a MEMS device at various stages of its fabrication.

As shown in FIGS. 2A and 2B, the first substrate 20 carries the MEMS devices 30, which are initially held immobile by sacrificial material 40. Depending on the function and design of the MEMS devices, they may be connected to substrate 20 in various ways. In the embodiment shown in the figures, post-release support structures 50 join the MEMS device to first substrate 20. In some MEMS embodiments, post-release support structures 50 may also serve as flexural elements and/or as electrical connections to the MEMS device. (For clarity, some post-release support structures 50 near the edges of the top plan views and not associated with any MEMS device 30 are intentionally omitted from the cross-section views. For a larger array, such structures may be used to support additional MEMS devices.)

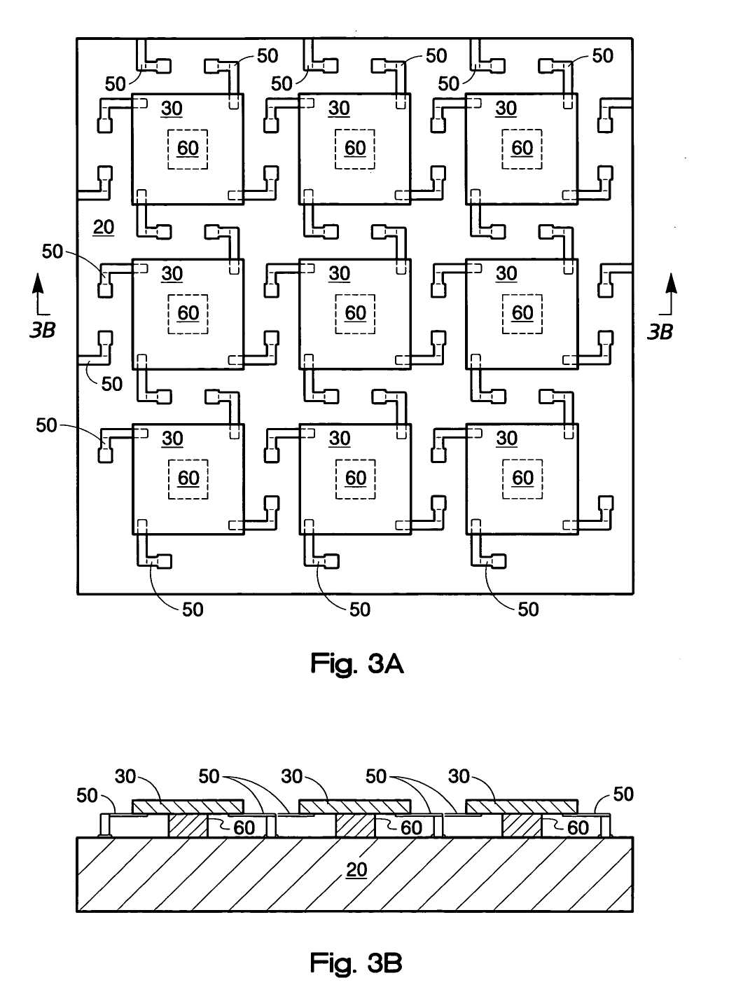

As shown in FIGS. 3A and 3B, the sacrificial material 40 may be partially removed, while leaving a portion 60 of the sacrificial material to be removed later. The remaining amount 60 of the sacrificial material is sufficient to hold the element(s) immobile until they are released later.

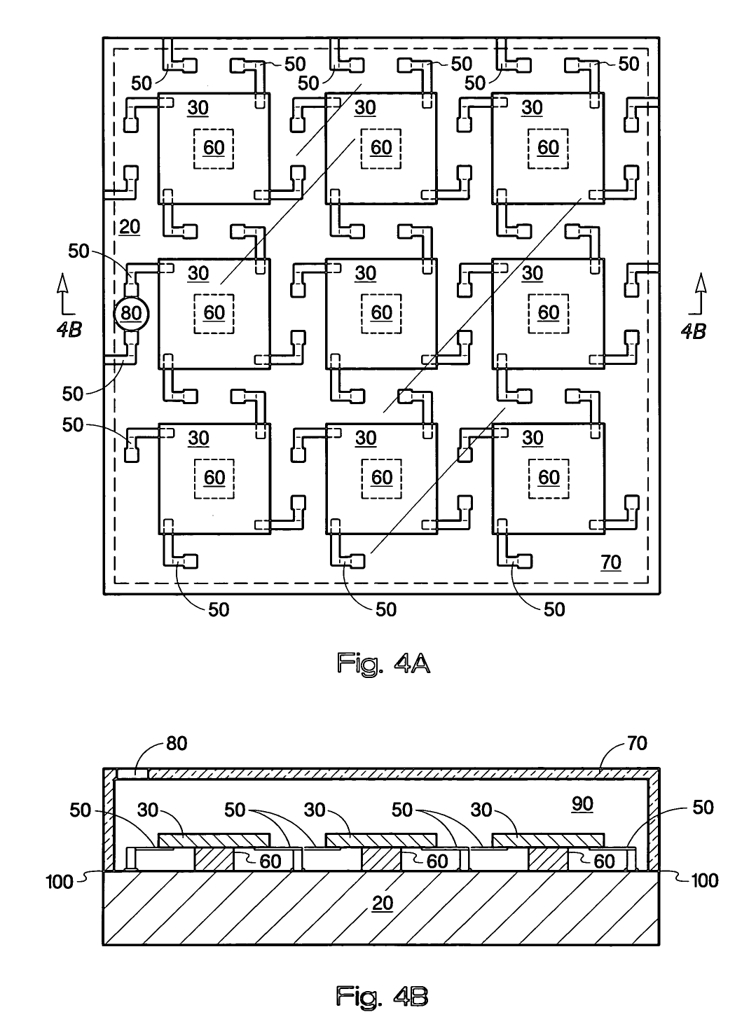

In the embodiment shown in FIGS. 4A and 4B, a second substrate 70 having a previously-formed release port 80 is bonded to first substrate 20, covering an enclosed space 90 for the MEMS devices 30. Bond 100 holds the second substrate to the first substrate at their common interface. FIG. 4A shows release port 80 disposed at a position laterally spaced apart from the MEMS devices 30. Various kinds of bonds 100 and methods for forming such bonds are described above in reference to step S60 of FIG. 1.

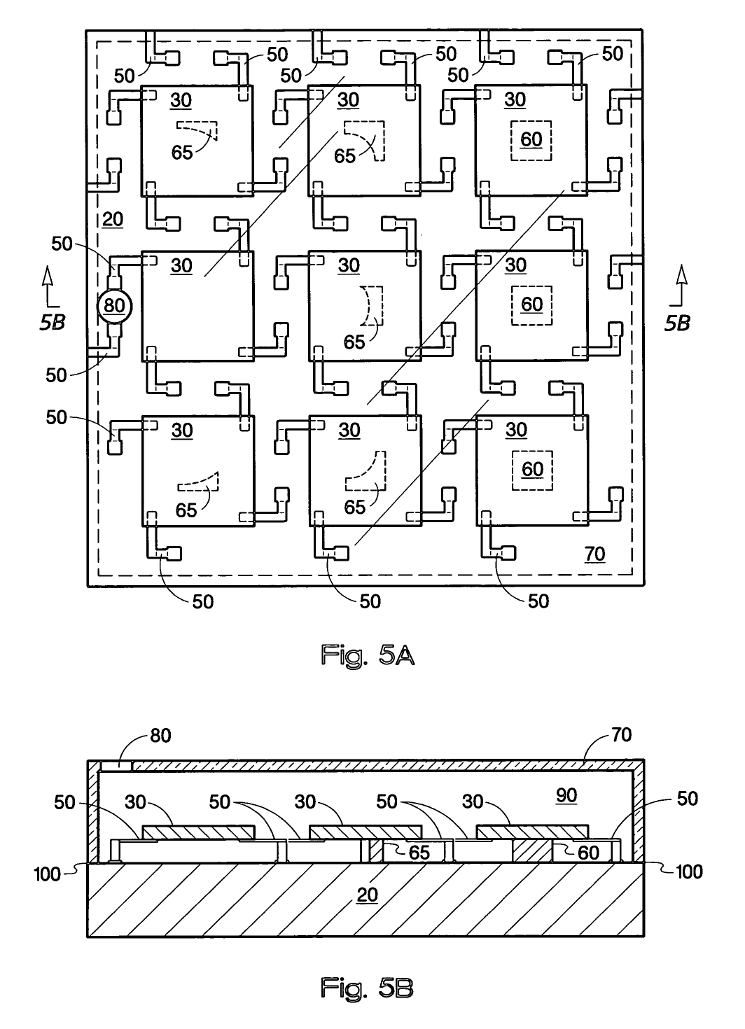

FIGS. 5A and 5B show this embodiment during removal of the remaining sacrificial material 60 through release port 80, but before the removal is complete. Some portions of the sacrificial material near release port 80 have been removed, some portions 60 far from release port 80 have not yet been substantially affected, and some smaller portions 65 at intermediate distance from release port 80 remain, having been only partially removed.

FIGS. 6A and 6B show this embodiment after all the sacrificial material 40, including any portions 60 or 65 previously left in place, has been completely removed through release port 80. In this completed embodiment 10 of the packaged MEMS device, release port 80 has been closed by a seal 110, after all the sacrificial material is removed and the MEMS devices 30 are no longer held immobile, i.e., after they have been fully released.

For some embodiments, release port 80 may be formed in the first substrate 20 instead of the second substrate 70. FIGS. 6A and 6B show (in phantom) such an alternative or optional additional release port 85 extending through the first substrate 20. Thus, another aspect of the invention provides embodiments of a packaged MEMS device 10 comprising a first substrate 20 carrying the MEMS device 30, the MEMS device including at least one element initially held immobile by a sacrificial material 40, the first substrate 20 having at least one release port 80 for removing the sacrificial material, a second substrate 70, and a bond joining the second substrate to the first substrate. Again, some embodiments of the packaged MEMS device may further comprise a seal 110 for closing the release port(s) after removing the sacrificial material to release the element initially held immobile.

The packaged MEMS device may be an integrated circuit or may form part of an integrated circuit.

Another aspect of the invention is a method of using a MEMS device requiring release of an element initially held immobile by a sacrificial material. This method includes carrying the MEMS device on a first substrate. A portion of the sacrificial material may be removed (e.g., by partial etching) without releasing the immobilized element(s), leaving an amount of sacrificial material sufficient to hold the element(s) immobile until they are released later. The MEMS device is covered with a cover formed by a second substrate. One or more post-bond release ports are provided, e.g., in either the first or second substrate. The second substrate is bonded to the first substrate without blocking any of the post-bond release ports, before removing all of the sacrificial material. The sacrificial material is completely removed through the post-bond release port(s) after bonding of the two substrates together to fully release the immobile element. This full release is performed before sealing the post-bond release port(s) if such sealing is required.

### INDUSTRIAL APPLICABILITY

Methods performed in accordance with the invention are useful in fabrication of many kinds of MEMS devices. The methods may be practiced on a wafer scale (i.e., before any dicing or singulation). Such MEMS devices may include high frequency switches, high Q capacitors, electromechanical motors, pressure transducers, accelerometers, and displays, for example. MEMS devices made in accordance with the invention are useful in many other sensor, actuator, and display applications, for example. MEMS devices made in accordance with the invention may be used in integrated circuits.

Although the foregoing has been a description and illustration of specific embodiments of the invention, various modifications and changes thereto can be made by persons skilled in the art without departing from the scope and spirit of the invention as defined by the following claims. For example, functionally equivalent materials may be substituted for the specific materials described in the embodiments, and the order of steps may be varied somewhat. For another example, although various embodiments are shown with one or more release ports through the first or second substrate, other locations for the release port(s) may be used in other embodiments. For some applications, various elements may be released at different times in the fabrication process; some may be released before bonding of the two substrates together, and some may be released after bonding, e.g., by using different sacrificial materials.

What is claimed is:

1. A method for fabricating a packaged MEMS device, comprising the steps of:
a) providing a first substrate,
b) forming the MEMS device on the first substrate, the MEMS device including at least one element initially held immobile by a sacrificial material,
c) providing a second substrate,
d) forming at least one release port,
e) bonding the second substrate to the first substrate, and
f) removing the sacrificial material through the at least one release port to release the element initially held immobile.

2. The method of claim 1, further comprising the step of:
g) sealing the at least one release port.

3. The method of claim 1, further comprising the step of:
h) removing a first portion of the sacrificial material before performing the step of bonding the second substrate to the first substrate, while leaving a second portion of the sacrificial material to be removed through the at least one release port.

4. The method of claim 1, wherein the first and second substrates both include a substantially planar portion.

5. The method of claim 1, wherein the first substrate comprises a material selected from the list consisting of silicon, an oxide of silicon, an oxynitride of silicon, a nitride of silicon, a metal, an oxide of a metal, an oxynitride of a metal, a nitride of a metal, and combinations thereof.

6. The method of claim 1, wherein the second substrate comprises a material selected from the list consisting of glass, quartz, alumina, silicon, an oxide of silicon, an oxynitride of silicon, a nitride of silicon, a metal, an oxide of a metal, an oxynitride of a metal, a nitride of a metal, and combinations thereof.

7. The method of claim 1, wherein the at least one release port extends through the second substrate.

8. The method of claim 1, wherein the at least one release port extends through the first substrate.

9. The method of claim 1, wherein the at least one release port is disposed to avoid alignment with the MEMS device.

10. The method of claim 1, wherein the at least one release port has an axis, and the axis is disposed to be laterally spaced apart from the MEMS device.

11. The method of claim 1, wherein the steps are performed in the order recited.

12. The method of claim 1, performed on a wafer scale, before any dicing or singulation.

13. A MEMS article made by the method of claim 1.

14. A method for fabricating a packaged MEMS device, comprising the steps of:
a) providing a first substrate,
b) forming the MEMS device on the first substrate, the MEMS device including at least one element initially held immobile by a sacrificial material,
c) removing a first portion of the sacrificial material without releasing the at least one element initially held immobile, while leaving a second portion of the sacrificial material to be removed later,
d) providing a second substrate,
e) forming at least one release port,
f) bonding the second substrate to the first substrate,
g) removing the second portion of the sacrificial material through the at least one release port to release the element initially held immobile.

15. The method of claim 14, further comprising the step of:
h) sealing the at least one release port.

16. The method of claim 14, wherein the first and second substrates each include at least a portion that is planar.

17. The method of claim 14, wherein the first substrate comprises a material selected from the list consisting of silicon, an oxide of silicon, an oxynitride of silicon, a nitride of silicon, a metal, an oxide of a metal, an oxynitride of a metal, a nitride of a metal, and combinations thereof.

18. The method of claim 14, wherein the second substrate comprises a material selected from the list consisting of glass, quartz, alumina, silicon, an oxide of silicon, an oxynitride of silicon, a nitride of silicon, a metal, an oxide of a metal, an oxynitride of a metal, a nitride of a metal, and combinations thereof.

19. The method of claim 14, wherein the at least one release port extends through the second substrate.

20. The method of claim 14, wherein the at least one release port extends through the first substrate.

21. The method of claim 14, wherein the at least one release port is disposed to avoid alignment with the MEMS device.

22. The method of claim 14, wherein the at least one release port has an axis, and the axis is disposed to be laterally spaced apart from the MEMS device.

23. A packaged MEMS device comprising:
a) a first substrate carrying the MEMS device, the MEMS device including at least one element initially held immobile by a sacrificial material,
b) a second substrate, at least one of the first and second substrates having at least one release port for removing the sacrificial material, and
c) a bond joining the second substrate to the first substrate.

24. The packaged MEMS device of claim 23, wherein the at least one release port extends through the first substrate.

25. The packaged MEMS device of claim 23, wherein the at least one release port extends through the second substrate.

26. The packaged MEMS device of claim 23, wherein at least one release port extends through each of the first and second substrates.

27. The packaged MEMS device of claim 23, further comprising a seal for closing the at least one release port after removing the sacrificial material to release the element initially held immobile.

28. An integrated circuit comprising the packaged MEMS device of claim 23.

29. A packaged MEMS device comprising:
a) means for carrying the MEMS device, the MEMS device including at least one element initially held immobile by a sacrificial material,
b) means for covering the MEMS device, at least one of the means for carrying and the means for covering having at least one means for removing the sacrificial material, and
c) means for joining the means for covering to the means for carrying.

30. The packaged MEMS device of claim 29, further comprising:
d) means for sealing the at least one means for removing the sacrificial material after removing the sacrificial material to release the element initially held immobile.

31. A method of using a MEMS device requiring release of an element initially held immobile by a sacrificial material, the method comprising the steps of:
a) carrying the MEMS device on a first substrate,
b) covering the MEMS device with a second substrate,
c) providing at least one post-bond release port,
d) bonding the second substrate to the first substrate without blocking the at least one post-bond release port, and
e) removing the sacrificial material through the at least one post-bond release port to release the element initially held immobile.

32. The method of claim 31, further comprising removing a portion of the sacrificial material before bonding the second substrate to the first substrate, while leaving an amount of sacrificial material sufficient to hold the element immobile until it is released later by performing step e).

33. The method of claim 31, further comprising sealing the at least one post-bond release port.
